(19) United States
(12) Patent Application Publication
(10) Pub. No.: US 2011/0192826 A1
(43) Pub. Date: Aug. 11, 2011

(54) Method of Monolithic Photo-Voltaic Module Assembly

(75) Inventors: Bodo Von Moltke, Berlin (DE); Frank Bothe, Berlin (DE); Lars Podlowski, Berlin (DE); Bert Plomp, Petten (NL); Mario Kloos, Petten (NL); Caroline Tjengdrawira, Petten (NL); Ian Bennett, Petten (NL); Paul De Jong, Petten (NL)

(73) Assignee: SOLLAND SOLAR ENERGY HOLDING B.V., Heerlen (NL)

(21) Appl. No.: 13/061,800

(22) PCT Filed: Sep. 4, 2009
(86) PCT No.: PCT/NL09/50534

§ 371 Date: Apr. 27, 2011

(30) Foreign Application Priority Data
Sep. 5, 2008 (NL) 2001958

(51) Int. Cl. B23K 1/005

(52) U.S. Cl. 219/121.64; 219/121.63

(57) ABSTRACT

An electrically conductive substrate is provided with a predetermined electrical pattern. A solder paste is deposited onto the electrically conductive substrate at pre-defined interconnection locations. A first encapsulant layer provided with a pattern of openings is placed onto the electrically conductive substrate. Back-contact solar cells are placed on the first encapsulant layer so as to have a match of the electrical pattern of the back-contact solar cells with the electrical pattern of the electrically conductive substrate. A second encapsulant layer is placed on the back-contact solar cells with a glass layer placed on the second encapsulant layer. Heat and pressure are applied to the components to cause the encapsulant materials to flow and form a monolithic photovoltaic module. A laser is applied to the solar cell from the side of the glass layer to cause the solder paste to reflow between each interconnection location and its matching connection location on the back-contact solar cell.

### FIELD OF THE INVENTION

The present invention relates to a method for manufacturing a photo-voltaic module assembly.

### BACKGROUND

A photo-voltaic (PV) module is a device comprising an array of solar cells that convert the solar energy directly into electricity.

One manner of achieving low-cost PV modules is the use of high-efficient thin back-contact solar cells. In back-contact solar cells conductive lines that are opaque to sunlight are located on the back side of the solar cell (back-contact pattern). Thus on the front side of the solar cell substantially no conductive lines are needed, resulting in a relatively larger area available to collect sunlight. Therefore, back-contact solar cells provide larger electrical current generation surface area, as compared to the conventional H-pattern solar cells, Also a reduction in the in-between cell spacing is achieved, leading to an overall increase in PV module electrical output.

To form such PV module a process flow is known from U.S. Pat. No. 5,972,732. In this process flow the following steps are carried out:

An electrically conductive substrate with a pre-defined electrical pattern is provided that matches the design of the back contact pattern of the back-contact solar cells to be installed.

Next, a solder paste is deposited onto the electrically conductive substrate at pre-defined interconnection locations on the predefined electrical pattern. The interconnection locations match with connection locations of the conductive lines on the back-contacted solar cell(s) for connecting the conductive lines to the electrical pattern.

Then, a pre-patterned first encapsulant layer is placed onto the electrically conductive substrate.

On the pre-patterned first encapsulant layer one or more back-contact solar cells are placed. The pattern of the pre-patterned first encapsulant layer is designed so as to allow connection between the back contact pattern of the solar cell and the electrical pattern on the electrically conductive substrate.

Next, a second encapsulant layer is placed on top of the solar cells.

Additionally, a top glass layer is placed on the second encapsulant layer.

Then, heat and pressure are applied to cause the first and second encapsulant materials to flow and form a monolithic laminate.

However, it is observed that like the encapsulant, the solder paste does reflow, but does not necessarily form electrical pathways. This has an adverse effect on the reliability of the process, since the state of the electrical connections is not well defined.

It is an object of the present invention to reduce the disadvantages of the process from the prior art.

### SUMMARY OF THE INVENTION

The object of the invention is achieved by a method as defined by the preamble of claim 1, wherein localized heat is applied at the interconnection locations utilizing a laser to couple its energy locally into the solar cell, so as to cause the solder paste to reflow between each interconnection location and its respective matching connection location on the back-contacted solar cell for establishing electrical interconnection between the back-contact solar cells and the electrically conductive substrate.

Advantageously, the laser annealing allows a controlled manner to deposit a well-defined amount of energy at (a) well defined location(s), which allows to improve the quality of the electrical connections between electrically conductive substrate and the one or more back-contact solar cells.

### BRIEF DESCRIPTION OF DRAWINGS

The invention will be explained in more detail below on the basis of a number of drawings, illustrating exemplary embodiments of the invention. The drawings are only intended to illustrate the objectives of the invention and should not be taken as any restriction on the inventive concept as defined by the accompanying claims.

FIG. 1 shows a schematic overview of the different layers in the back-contact solar cell module.

FIG. 2 shows a partially exploded view of a PV module to illustrate describing how the interconnection between the solar cells and the conductive substrate is established.

FIGS. 3a and 3b show the process of applying heat and pressure on the module assembly to achieve a monolithic laminate.

FIGS. 4a and 4b show an embodiment of the invention of a laser soldering process to establish the electrical pathways between solar cells and electrical conductive substrate.

FIG. 5 shows a second embodiment of the invention of a laser soldering process to establish the electrical pathways between solar cells and electrical conductive substrate.

FIG. 6 shows typical cross-sectional microscopic views of a laser-soldered joint in PV module.

FIG. 7 shows a laser beam device for module assembly according to an embodiment of the present invention.

### DETAILED DESCRIPTION

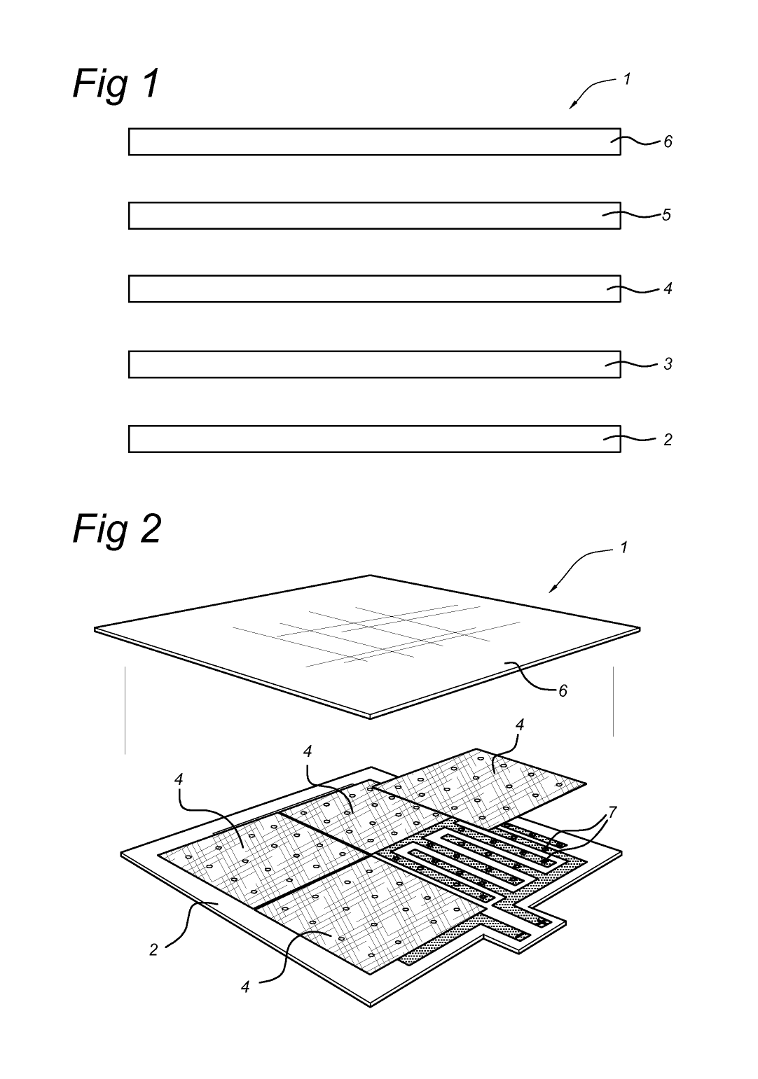

FIG. 1 shows the overview of the different layers in the construction of the back-contact solar cell module laminate 1. From bottom-to-top, the laminate 1 comprises or is built up from a conductive substrate 2, a rear-side perforated first encapsulant layer 3, back-contact solar cells 4, a top second encapsulant layer 5 and a glass plate 6 on top. These layers are placed subsequently through the assembly process.

The conductive substrate 2 can be of any type such as tedlar-PET-copper, tedlar-PET-aluminium, but also on alternative structures that are glass based, epoxy based, or coated PET, etc. In an embodiment the electrically conductive substrate is constructed from a stack of layers comprising at least one layer having a function of mechanical rigidity such as PET, glass, fiber reinforced epoxy, etc, at least one layer having a function of UV blocking (such as tedlar, PVDF, etc) and at least one layer having a function of electrical conductivity (such as copper, aluminium, etc).

Back-contact solar cells 4 can be of any type such as metal-wrap through (MWT), emitter wrap through (EWT), back-junction (BJ), heterojunction (HJ), etc.

FIG. 2 is a more detailed schematic describing how the interconnection between the solar cells and the conductive substrate is established. This picture does not show the encapsulant layers for the sake of simplicity. The substrate pattern on the conductive substrate 2 is defined to match the electrical pattern of the back-contact solar cells 4. Solder paste 7 is applied to each of the interconnection locations (indicated by white dots on substrate 2), either onto the solar cell, or onto the conductive substrate. The solar cells 4 are then automatically positioned onto the conductive substrate 2 such that the positions are matched.

Interconnection material can be of any type of solder paste 7 with metal combinations such as tin-lead, tin-bismuth, tin-lead-silver, tin-copper, tin-silver, etc.

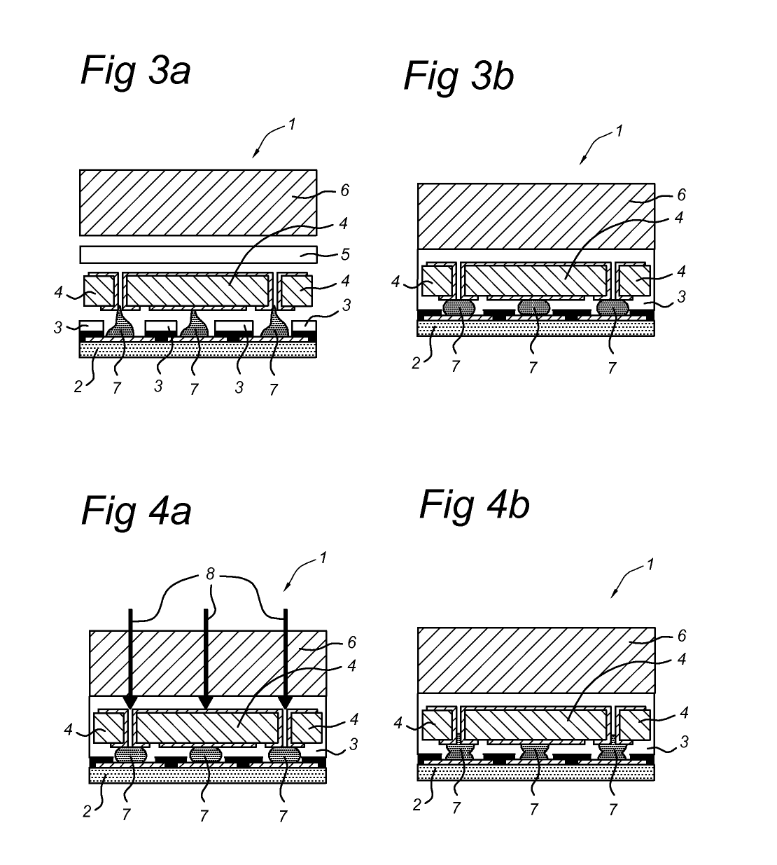

FIGS. 3a and 3b illustrate the process of applying heat and pressure on the module assembly to achieve a monolithic laminate. FIG. 3a shows the situation in the assembly process after the following steps:

Providing the electrically conductive substrate 2 with a pre-defined electrical pattern;

Depositing solder paste 7 onto the electrically conductive substrate at pre-defined interconnection locations on the predefined electrical pattern;

Placing a pre-patterned first encapsulant layer 3 onto the electrically conductive substrate 2 with solder paste 7 at selected locations in between;

Placing on the pre-patterned first encapsulant layer 3 one or more back-contact solar cells 4 while matching the electrical pattern of the back solar cells with the electrical pattern on the conductive substrate 2;

Next, placing a second encapsulant layer 5 on top of the solar cells 4, and placing a top glass layer 6 on the second encapsulant layer 5.

The encapsulant layers may consist of a rubber-adhesive material, for example ethylene vinyl acetate (EVA). Additionally, this material can be a thermo-setting material as well as a thermoplastic material, such as polyethylene (PE), polyurethane (PU), etc.

FIG. 3b shows the situation after applying heat and pressure on the assembled layers 2,3,4,5,6.

As shown in FIG. 3b, like the encapsulants 3, 5, the solder paste 7 does reflow, but does not necessarily form electrical pathways.

FIGS. 4a and 4b illustrate an embodiment of the invention for a laser soldering process to establish the electrical pathways between solar cells 4 and electrical conductive substrate 2.

The method of the present invention comprises a process step wherein localized heat is applied at the interconnection locations utilizing a laser to couple its energy locally into the solar cell, so as to cause the solder paste to reflow between each interconnection location and its respective matching connection location on the back-contacted solar cell for establishing electrical interconnection between the back-contact solar cells and the electrically conductive substrate.

FIG. 4a shows the situation while applying laser generated heat at the predefined interconnection locations associated by the locations of the solder 7 in the module 1.

Laser-applied heat (indicated by arrows 8) is coupled onto the front-side of the solar cells at the interconnection locations to locally melt the solder paste 7 on the cell's rear side.

FIG. 4b shows the situation of a PV module 1 where reflow of the solder paste 7 has occurred.

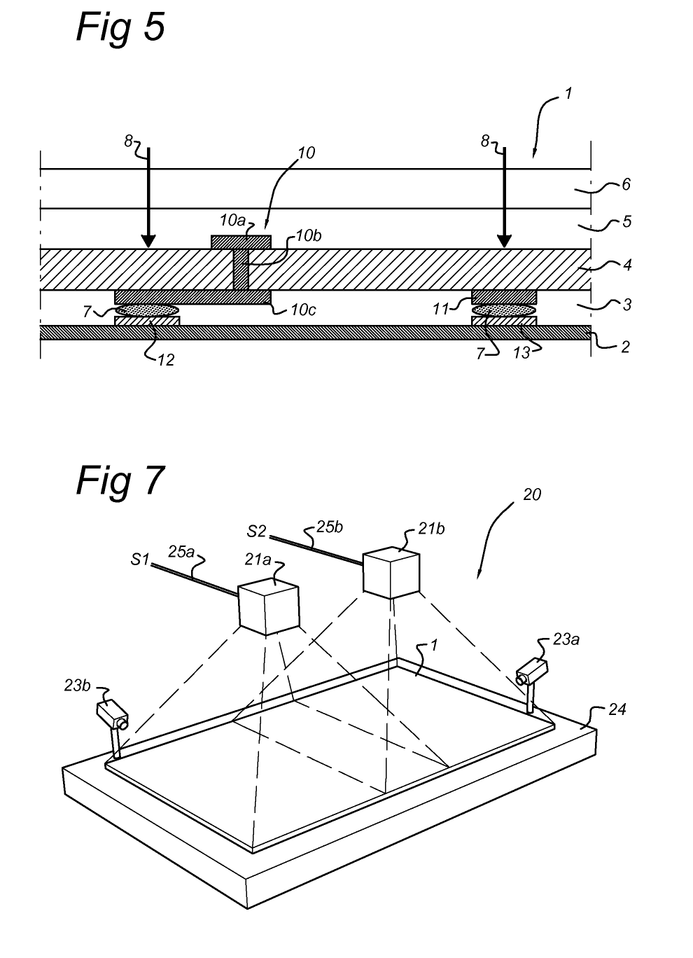

FIG. 5 shows a second embodiment of the invention of a laser soldering process to establish the electrical pathways between solar cells and electrical conductive substrate.

In the second embodiment the PV module comprises a conductive substrate 2, a pre-patterned first encapsulant layer 3, a back-contact solar cell 4, a second encapsulant layer 5 on top of the solar cell 4, and a top glass layer 6, which are stacked on each other in a vertical direction Y.

The back-contact solar cell 4 is provided with a front-to-back interconnect 10 and a back-contact 11.

The front-to-back interconnect 10 is arranged for contacting a front metallization pattern 10a to the back surface of the back-contact solar cell 4 and comprises the front metallization pattern 10a, at least one via 10b and a back-interconnect 10c. The front metallization pattern 10a is connected to the at least one via 10b, and the at least one via 10b is connected to the back-interconnect 10c. The at least one via 10b is arranged as a conductive metal path through the semiconductor substrate 4. The back interconnect 10c is arranged for connecting to a respective corresponding first contact 12 on the pre-defined electrical pattern of the electrically conductive substrate 2.

The back-contact 11 is arranged for connecting to a respective corresponding second contact 13 on the pre-defined electrical pattern of the electrically conductive substrate 2.

The method to configure the PV module is similar to what is described above with reference to FIG. 3a:

Providing the electrically conductive substrate 2 with a pre-defined electrical pattern;

Depositing solder paste 7 onto the electrically conductive substrate at pre-defined interconnection locations on the predefined electrical pattern;

Placing a pre-patterned first encapsulant layer 3 onto the electrically conductive substrate 2 with solder paste 7 at selected locations in between;

Placing on the pre-patterned first encapsulant layer 3 one or more back-contact solar cells 4 while matching the electrical pattern of the back solar cells with the electrical pattern on the conductive substrate 2;

Next, placing a second encapsulant layer 5 on top of the solar cells 4, and placing a top glass layer 6 on the second encapsulant layer 5.

In the second embodiment, the back interconnect 10c is extended in a horizontal direction X relative to the position of the via 10b while the respective corresponding first contact 12 is displaced accordingly in the horizontal direction X relative to the position of the via 10b.

Next, the method of the present invention comprises a process step wherein localized heat is applied at the interconnection locations utilizing a laser to couple its energy locally into the solar cell, so as to cause the solder paste to reflow between each interconnection location and its respective matching connection location on the back-contacted solar cell for establishing electrical interconnection between the back-contact solar cells and the electrically conductive substrate.

Laser-applied heat (indicated by arrows 8) is coupled (e.g. by focusing) onto the front-side of the solar cells at the interconnection location of the back side first contact 12 to the back interconnect 10c and at the interconnection location of the back side second contact 13 to the back-contact 11 to locally melt the solder paste 7 at the first and second contacts 12, 13 on the cell's rear side.

Advantageously by extending the back interconnect horizontally with respect to the via and by accordingly displacing the corresponding first contact 12, the method avoids that the laser heating must heat also the metal of the front interconnection 10a and the via's metal, in stead the method provides that heating of the contacts to be soldered is by laser irradiation through portions of the silicon substrate not covered by metal. Consequently, less energy is required for heating and melting the solder paste at the back side first contact 12. Also, focusing of the laser beam is improved in comparison to focusing on a metallic surface.

It is experimentally observed that according to the second embodiment the required energy can be reduced from about 40 J to about 26 J for a PV module (i.e. by about 35%). By reducing the energy input, the heat load is also reduced and the production process becomes more robust.

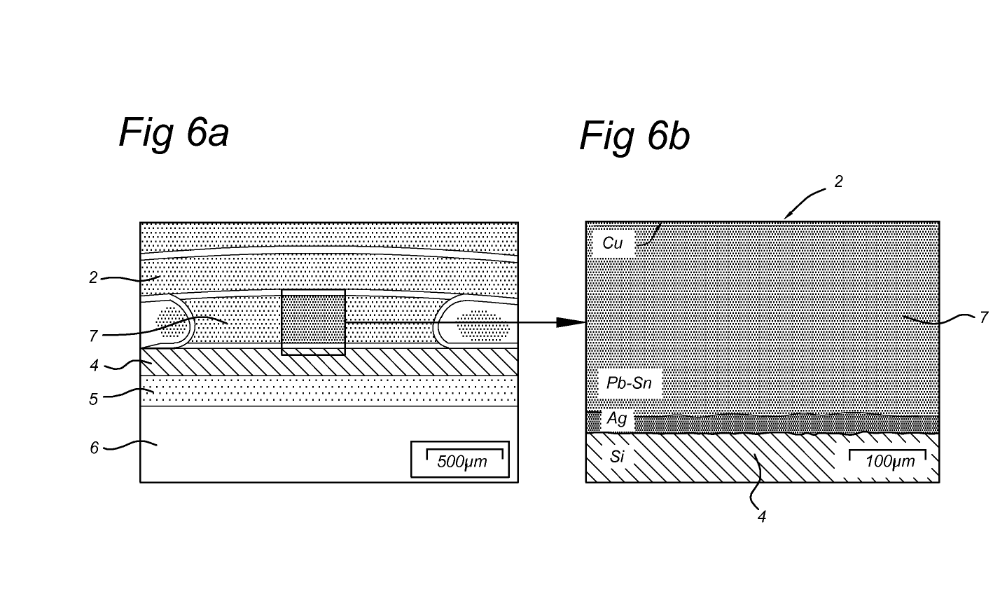

FIG. 6 shows the proof of the invention by a first microscopic cross-sectional view 6A and a second microscopic cross-sectional view 6B. The first microscopic cross-sectional view 6A shows a cross-sectional view of the laser-soldered joint 7 between conductive substrate 2 and back-contacted solar cell 4. The molten solder paste 7 shows a good interface to both of the contact surfaces, i.e., the electrical conductive substrate 2 and the solar cells 4.

The second microscopic cross-sectional view 5B shows the laser-soldered joint 7 in more detail.

It is noted that a state-of-the-art automated one-step module assembly line using the method of the present invention may provide a high throughput process, eliminating many manual handling steps that contributes to module assembly yield loss. The one step module assembly process in addition allows for the interconnection of the solar cells to be established in an automated high throughput fashion. The laser system can be controlled to generate localized heat on the module at the predefined interconnection locations.

FIG. 7 shows a laser beam device 20 for module assembly according to an embodiment of the present invention.

The laser beam device is arranged for soldering a back contact 10c; 11 of a solar cell 3 to a contact 12; 13 of an electrically conductive substrate 2 by means of a solder paste 7 as described above. Soldering is carried out by application of heat at the location of the solder paste by a laser beam generated by the laser beam device.

According to the present invention, the laser beam device comprises at least one laser beam source, at least one galvo scanner (galvanometer scanner), a support for a photovoltaic module and position sensors.

In an embodiment, the laser beam device 20 comprises a first and a second laser beam source S1, S2, a first and a second galvo scanner 21a, 21b, a support 24 for a photovoltaic module 1 and position sensors 23a, 23b. In this embodiment, by using a double system of laser sources and galvo scanners, the throughput of the laser beam device is relatively enhanced. This may be useful to have a throughput for soldering which is comparable to the throughput of other stages of the module assembly process.

The first laser source S1 is arranged for generating a laser beam 25a which is directed by means of the first galvo scanner 21a to an area portion of the front surface of the photovoltaic module 1. Similarly, the second laser source S2 is arranged for generating a second laser beam 25b which is directed by means of the second galvo scanner 21b to a further area portion of the front surface of the photovoltaic module 1.

The first and second galvo scanner are each arranged for XY scanning, i.e. the galvo scanner is capable of directing a laser beam in two orthogonal directions so as to point the laser beam at a given location on an area on a surface.

The laser source S1; S2 is capable of generating a laser beam with high beam quality (i.e., a substantially parallel beam). In an embodiment, the laser source is a fibre laser source. Further the laser source is arranged with beam shaping optics (i.e., a system of lenses). The use of a high beam quality and beam shaping ensures the control of the laser beam diameter at the level of the photovoltaic module.

During use, the laser beam device directs the laser beam(s) across the surface of the photovoltaic module to point at the locations of the solder paste and locally heat the solder paste to reflow between the associated back contact 10c; 11 of the solar cell 3 and contact 12; 13 of the electrically conductive substrate 2. The movement and positioning of the laser beam(s) on the surface is controlled by the corresponding galvo scanner.

The position sensors 23a, 23b are arranged to identify the position of the photovoltaic module relative to a reference point. From the position of the photovoltaic module the position of the solder positions can be derived.

In an embodiment, the position sensors comprise two cameras which are arranged to capture images of the area on the support which encompasses the photovoltaic module.

In an embodiment, the position sensors are arranged as cameras at reference positions on the support. The cameras may be arranged along two sides of the photovoltaic module. Alternatively, the cameras may be arranged along one side of the module.

In an alternative embodiment, the position sensors are arranged as cameras which look at the surface of the photovoltaic module through the galvo scanners.

Identification of the position of the photovoltaic module can be achieved by capturing an image of the position of the laser beam(s) scattering from the front surface of the photovoltaic module.

The information of measurements by the two cameras is sufficient to calculate the position of the photovoltaic module relative to the galvo scanner position.

Additionally, in an embodiment, a further camera (not shown) can be placed behind the at least one galvo scanner for looking through the galvo scanner at the (positions of the) front contacts of the solar panels, so as to enhance the accuracy of the galvo scanner and to rule out displacements of the individual solar cells.

In an embodiment, the laser beam device is arranged for compensation of differences in absorption of laser radiation in the photovoltaic module that are caused by different angles (and different reflections) of the laser beam on the surface. Compensation may be achieved using a calibration table that indicates a relative loss of laser beam energy as a function of the laser beam angle on the front surface. Such a loss of laser beam energy can be determined experimentally by measuring laser beam energy by a power measurement device with a similar glass cover as on the photovoltaic module. The laser beam is arranged to impinge on the front surface of the glass cover, while the power measurement device is arranged at the back surface of the glass cover and directed towards the impinging laser beam.

In an embodiment, the laser beam source generates a laser beam with a near-infra-red wavelength, for example 1064 nm. It is noted that the cameras used as position sensors are capable of detecting radiation of that wavelength.

Advantageously, the laser beam device overcomes the problem of the large size of solar modules which would make it impractical to move the panel itself during soldering. According to the invention, the best way is to leave the module at it's position and move the laser beam. The scanner calibration by the cameras using capturing an image of (a low amount of laser radiation of) the laser beam impinging on the surface of the photovoltaic module relaxes the need for accurate handling of the module. As a result of the movement of the laser beam(s) in stead of the photovoltaic module, the build-up of the laser beam device can become less rigid and can be integrated into another process station. This will reduce the costs of such a process station considerably.

Furthermore, it is noted that by using a laser beam with a high beam quality (i.e. with a beam propagation factor M²≈1) and by generating the laser beam to be parallel, the laser beam device can be arranged to have a relatively long working distance between the galvo scanner and the front surface of the photovoltaic module. Using a wavelength of 1064 nm and M²≈1 the working distance can be about 2 meter.

In a further embodiment, the laser beam device comprises a further laser source and a further galvo scanner. The further laser source is arranged for generating a further laser beam which is directed by means of the further galvo scanner to the back surface of the photovoltaic module 1. The support in this embodiment is an open construction arranged to allow the further laser beam to impinge on the back surface of the photovoltaic module. In this manner, the laser beam device is arranged to apply heat locally at the back surface of the photovoltaic module. Since the electrically conductive substrate allows a partially transmission of the laser beam radiation, the laser beam device is capable of heating the back contact material of the electrically conductive substrate which is located on the side of the electrically conductive substrate facing the solar cell. In this manner, the heat input to the area of the solder weld can be enlarged which results in an increase of the local temperature of the laser beam irradiated area. In this way, the soldering process can be enhanced.

It is noted that the first, second laser sources and if present also the further laser source can be individual laser sources that each can generate a laser beam. Alternatively, the laser sources may be embodied by a single laser source in combination with beam splitter(s) which during use can generate separate laser beams.

Moreover, it is noted that the above described in-laminate laser soldering has the advantage of providing mechanical support to the fragile solar cells during the soldering process. As a result, solar cells do not break, resulting in reduced yield losses. This technology enables the use of extremely thin (<160 μm) crystalline silicon solar cells.

Other alternatives and equivalent embodiments of the present invention are conceivable within the concept of the invention, as will be clear to a person skilled in the field. The concept of the invention is limited only by the accompanying claims.

1. A method for manufacturing of a photo-voltaic module comprising:
a) providing an electrically conductive substrate, the substrate being provided with a predetermined electrical pattern;
b) depositing a solder paste onto the electrically conductive substrate at pre-defined interconnection locations;
c) placing a first encapsulant layer provided with a pattern of openings onto the electrically conductive substrate, the pattern of openings corresponding with the locations of the solder paste;
d) placing at least one back-contact solar cell on the first encapsulant layer so as to have a match of the electrical pattern of the back-contact solar cells with the electrical pattern of the electrically conductive substrate;
e) placing a second encapsulant layer on the at least one back-contact solar cell, and placing a glass layer on the second encapsulant layer;
f) applying heat and pressure to the components to cause the encapsulant materials to flow and form a monolithic photovoltaic module, characterised by local application of heat at the interconnection locations utilizing a laser to couple its energy locally into the at least one solar cell from the side of the glass layer, so as to cause the solder paste to reflow between each interconnection location and its respective matching connection location on the at least one back-contact solar cell for establishing electrical interconnection between the at least one back-contact solar cell and the electrically conductive substrate.

2. The method according to claim 1, wherein the predefined connection location comprises a front-to-back interconnect; the front-to-back interconnect comprising a front-side metallization pattern, at least one via and at least one back-side interconnect, the front-side metallization pattern being connected to the at least one via and the at least one via being connected to the at least one back-side interconnect; the back-side interconnect being arranged for connection with a corresponding connection location by means of the solder paste and the back side interconnect extending in a direction along the back-side of the substrate, so as to have the corresponding connection location being displaced compared to the position of the front-side metallization pattern and to the position of the at least one via in the same direction along the back-side of the substrate.

3. The method according to claim 1, wherein the local application of heat at the interconnection locations utilizing a laser to couple its energy locally into the at least one solar cell from the side of the glass layer comprises focusing the laser beam on a silicon front-side surface of the at least one contacted solar cell.

4. The method according to claim 1, wherein the local application of heat at the interconnection locations utilizing a laser comprises using a laser beam device, the laser beam device comprising at least one laser beam source, at least one galvo scanner, a support for a photovoltaic module and position sensors; the at least one laser beam source being arranged for generating a laser beam which is directed by means of the at least one galvo scanner to an area portion of the front surface of the photovoltaic module.

5. The method according to claim 4, wherein the position sensors are arranged to identify the position of the photovoltaic module on the support.

6. The method according to claim 4, wherein the position sensors are arranged as cameras at reference positions on the support.

7. The method according to claim 4, wherein the position sensors are arranged as cameras which look at the surface of the photovoltaic module through the at least one galvo scanner.

8. The method according to claim 1, comprising compensating differences in absorption of laser radiation in the photovoltaic module that are caused by different angles of the at least one laser beam on the surface.

9. The method according to claim 1, wherein the electrically conductive substrate is selected from a group comprising tedlar-PET-copper, tedlar-PET-aluminum, or a structure based on glass, epoxy or coated PET.

10. The method according to claim 1, wherein the electrically conductive substrate is constructed from a stack of layers comprising at least one layer having a function of mechanical rigidity, at least one layer having a function of UV blocking and at least one layer having a function of electrical conductivity.

11. The method according to claim 1, wherein the type of the back-contact solar cells is selected from a group comprising: metal-wrap through (MWT), emitter wrap through (EWT), back-junction (BJ), and heterojunction (HJ).

12. The method according to claim 1, wherein the solder paste can consist of an alloy selected from a group comprising tin-lead, tin-bismuth, tin-lead-silver, tin-copper and tin-silver.

13. A laser beam device for manufacturing of a photo-voltaic module, the photovoltaic module comprising:
a) an electrically conductive substrate, the substrate being provided with a predetermined electrical pattern;
b) a solder paste on the electrically conductive substrate at pre-defined interconnection locations;
c) a first encapsulant layer provided with a pattern of openings on the electrically conductive substrate, the pattern of openings corresponding with the locations of the solder paste;
d) at least one back-contact solar cell on the first encapsulant layer so as to have a match of the electrical pattern of the back-contact solar cells with the electrical pattern of the electrically conductive substrate;
e) a second encapsulant layer on the at least one back-contact solar cell, and a glass layer on the second encapsulant layer;
wherein the laser beam device is arranged for applying heat and pressure to the components to cause the encapsulant materials to flow and form a monolithic photovoltaic module, characterised by local application of heat at the interconnection locations utilizing the laser to couple its energy locally into the at least one solar cell from the side of the glass layer, so as to cause the solder paste to reflow between each interconnection location and its respective matching connection location on the at least one back-contact solar cell for establishing electrical interconnection between the at least one back-contact solar cell and the electrically conductive substrate; the laser beam device comprising at least one laser beam source, at least one galvo scanner, a support for a photovoltaic module and position sensors; the at least one laser beam source being arranged for generating a laser beam which is directed by means of the at least one galvo scanner to an area portion of the front surface of the photovoltaic module.
